(19) United States
(12) Patent Application Publication
(10) Pub. No.: US 2023/0209937 A1
(43) Pub. Date: Jun. 29, 2023

(54) ORGANIC LIGHT EMITTING DISPLAY DEVICE AND MANUFACTURING METHOD THEREOF

(71) Applicant: DB HiTek Co., Ltd., Bucheon-si (KR)

(72) Inventors: Sang Il HWANG, Wonju-si (KR); Dae Il KIM, Cheongju-si (KR); Nam Kyu KIM, Osan-si (KR)

(21) Appl. No.: 18/064,888

(22) Filed: Dec. 12, 2022

(30) Foreign Application Priority Data
Dec. 27, 2021 (KR) 10-2021-0188526

(51) Int. Cl. H10K 59/131; H10K 50/818; H10K 71/00

(52) U.S. Cl. CPC H01L 27/3276; H01L 51/56; H01L 51/5218; H01L 27/3258

(57) ABSTRACT

Disclosed is an organic light emitting display device, and more particularly, an organic light emitting display device having a fence structure between a pixel region and which covers edge or peripheral portions of adjacent first electrodes that include an anode. The organic light emitting display device increases isolation characteristics by preventing crosstalk between adjacent pixel regions, and prevents certain defects that may occur during subsequent processing (e.g., following formation of a reflective electrode).

### CROSS REFERENCE TO RELATED APPLICATION

The present application claims priority to Korean Patent Application No. 10-2021-0188526, filed Dec. 27, 2021, the entire contents of which are incorporated herein for all purposes by this reference.

### BACKGROUND OF THE INVENTION

### Field of the Invention

The present disclosure relates to an organic light emitting display device. More particularly, the present disclosure relates to an organic light emitting display device having a fence structure between a pixel region and which covers edge or peripheral portions of adjacent first electrodes that include an anode, the organic light emitting display device increasing isolation characteristics and/or preventing crosstalk between adjacent pixel regions, and preventing defects that may occur in subsequent processing (e.g., following formation of a reflective electrode).

### Description of the Related Art

Recently, as society has entered the Information Age, the field of displays that visually express electrical signals as information has rapidly developed, and various flat display devices having excellent qualities such as thinness, lightness, low power consumption, etc. have been developed. Specific examples of flat display devices include a liquid crystal display (LCD) device, a plasma display panel (PDP), a field-emission display (FED) device, an organic light emitting display (OLED) device, etc.

In particular, the organic light emitting display device uses self-luminous elements, and has a faster response rate, greater luminous efficiency, higher luminance, and a wider viewing angle than other flat display devices. Furthermore, the organic light emitting display device may have a high resolution and be implemented as a large screen, so that the organic light emitting display device has attracted attention as a next-generation display device. In an organic light emitting diode, an organic light emitting layer is between two electrodes (an anode and a cathode).

Electrons and holes from the two electrodes are respectively injected into the organic light emitting layer so as to generate excitons caused by the combination of the electrons and the holes. In addition, the organic light emitting diode applies a principle in which light is generated when the excitons go from an excited state into a ground state.

FIG. 1 is a cross-sectional view illustrating a conventional organic light emitting display device.

In describing a conventional organic light emitting display device 900 with reference to FIG. 1, an insulation film 910 covers an upper metal layer 930, and a lower electrode 920 (i.e., the anode) is on the insulation film 910 in each pixel region. The lower electrode 920 may be covered by an uppermost insulating or passivation layer 950, a planarization layer 960, and a color filter layer 940. The color filter layer 940 may comprise color filter materials, such as a red color filter 940a, a green color filter 940b, or a blue color filter 940c over a corresponding lower electrode 920, through which the light passes. An individual color filter material may correspond to an individual pixel region.

Here, a reflective electrode 921 is under the lower electrode 920, and one or more subsequent processes are performed while sidewalls of the reflective electrode 921 are exposed. In detail, when the sidewalls of the reflective electrode 921 are exposed (e.g., during ashing or thermal treatment), a defect caused by corrosion or precipitation at the surface of the reflective electrode 921 may occur since the reflective electrode 921 includes silver and/or aluminum (which may have a relatively low melting point). Therefore, problems may arise, including a decrease in the reflectivity of the reflective electrode 921, and a leakage path between adjacent pixel regions may form.

To solve such problems, the inventors of the present disclosure provide a new organic light emitting display device and a method of manufacturing the organic light emitting display device that has an improved structure, described in detail below.

### Document of Related Art

Korean Patent Application Publication No. 10-2015-0038982, entitled “ORGANIC LIGHT EMITTING DISPLAY DEVICE AND MANUFACTURING METHOD OF THE SAME.”

### SUMMARY OF THE INVENTION

Accordingly, the present disclosure has been made keeping in mind the above problems that may occur in the related art.

An objective of the present disclosure is to provide an organic light emitting display device and a method of manufacturing the organic light emitting display device in which a fence structure extends to a position higher than first electrodes and is between the first electrodes between adjacent pixel regions, thereby blocking a leakage current path of a side surface of each pixel region.

In addition, another objective of the present disclosure is to provide an organic light emitting display device and a method of manufacturing the organic light emitting display device in which a fence structure covers a sidewall of the reflective electrode, thereby preventing a defect that might otherwise occur due to corrosion and/or precipitation at the surface of the reflective electrode during ashing, thermal treatment, or another subsequent process.

In addition, still another objective of the present disclosure is to provide an organic light emitting display device and a method of manufacturing the organic light emitting display device in which an upper contact (e.g., connecting an upper metal wiring and a first electrode) is at an edge or peripheral portion of the first electrode such that the upper contact overlaps the fence structure in a vertical direction, thereby preventing a reflective electrode performing a light-reflecting function from bending, and maintaining optical characteristics (e.g., of the organic light emitting display device).

The present disclosure may be implemented by one or more embodiments having some or all of the following configurations, to achieve one or more of the above-described objectives.

According to one or more embodiments of the present disclosure, there is provided an organic light emitting display device including metal wirings; an insulation film covering the metal wirings; first electrodes on the insulation film; contacts electrically connecting each of the first electrodes to the corresponding metal wirings; and a fence structure on the insulation film between adjacent pixel regions and configured to cover only a part of adjacent ones of the first electrodes .

In the organic light emitting display device of the present disclosure, the fence structure may cover a sidewall of each of the (adjacent) first electrodes.

In the organic light emitting display device of the present disclosure, the fence structure may include a lower film on a sidewall and an edge or peripheral portion of an uppermost surface of each of the first electrodes and on the insulation film between the adjacent pixel regions; and an upper film on the lower film.

In the organic light emitting display device of the present disclosure, the fence structure may have a polygonal frame shape.

In the organic light emitting display device of the present disclosure, each of the contacts may contact (e.g., be connected to) a corresponding one of the first electrodes at an edge or side of the corresponding first electrode, and each of the contacts may overlap the fence structure in a vertical direction.

According to one or more other embodiments of the present disclosure, there is provided an organic light emitting display device including a substrate; a gate electrode on or over the substrate; a source and a drain on the substrate; metal wirings on the substrate (e.g., comprising a multilayered wiring structure); an insulation film covering the metal wirings; a first electrode in each pixel region, the first electrode being on the insulation film; an contact electrically connecting each first electrode to a corresponding metal wiring; and a fence structure on the insulation film between adjacent pixel regions and having a height greater than each of the first electrodes.

In the organic light emitting display device of the present disclosure, each contact may contact an edge or peripheral portion of the corresponding first electrode.

In the organic light emitting display device of the present disclosure, each first electrode may include a buffer electrode on the insulation film; a reflective electrode on the buffer electrode; and an anode on the reflective electrode.

In the organic light emitting display device of the present disclosure, the fence structure may cover a sidewall (e.g., all sidewalls) of the reflective electrode.

In the organic light emitting display device of the present disclosure, the fence structure may be between the adjacent pixel regions and may cover sidewalls and edge or peripheral portions of an upper surface of the adjacent first electrodes.

According to one or more embodiments of the present disclosure, there is provided a method of manufacturing an organic light emitting display device, the method including forming an contact in an insulation film; forming a first electrode on the insulation film in each pixel region; and forming a fence structure between adjacent first electrodes to cover only sidewalls and edge or peripheral portions of an uppermost surface of adjacent first electrodes.

In the method of the present disclosure, forming the fence structure may include depositing a first insulation film on the insulation film between adjacent pixel regions and on the sidewalls and the adjacent first electrodes; and depositing a second insulation film on the first insulation film.

In the method of the present disclosure, forming the fence structure may further include etching the second insulation film; and opening center portions of the adjacent first electrodes by etching the first insulation film.

In the method of the present disclosure, forming the contact may include forming a contact hole by etching the insulation film to expose a metal wiring; filling the contact hole with a conductive material; and removing any conductive material on an uppermost surface of the insulation film, wherein the contact is connected to the edge or peripheral portion of each first electrode.

In the method of the present disclosure, the first insulation film may function as an etch stop for the second insulation film.

According to one or more other embodiments of the present disclosure, there is provided a method of manufacturing an organic light emitting display device, the method including stacking a metal wiring and an insulation film repeatedly on a substrate including a source and a drain such that the metal wiring forms a multilayered wiring structure; forming a contact in the insulation film; forming a first electrode on the insulation film in each pixel region, the first electrode comprising a reflective electrode; and forming a fence structure on the insulation film between adjacent pixel regions.

In the method of the present disclosure, the first electrode may include a buffer electrode on the insulation film; the reflective electrode on the buffer electrode; and an anode on the reflective electrode, wherein the fence structure covers a sidewall of the reflective electrode.

In the method of the present disclosure, the method may further include forming an organic light emitting layer on the anode; and forming a common electrode on the organic light emitting layer.

According to the above configurations, the present disclosure has the following effects.

In the present disclosure, since the fence structure extends to a position higher than the first electrodes and is between the first electrodes in the adjacent pixel regions, a potential leakage current path (e.g., through a side surface) between the pixel regions is blocked.

In addition, in the present disclosure, since the fence structure covers the sidewalls of the reflective electrode, defects that might otherwise be caused by corrosion and/or precipitation at the surface of the reflective electrodes are prevented during subsequent ashing or thermal treatment processes.

In addition, in the present disclosure, since the contact connected to the metal wiring and the first electrode is at an edge or peripheral portion of the first electrode such that the fence structure overlaps the contact in the vertical direction, the reflective electrode (which performs a light-reflecting function) is prevented from bending, thereby maintaining optical characteristics (e.g., of the OLED pixel or display).

Meanwhile, even though not explicitly mentioned, effects described in the present specification and possible effects expected from the technical features of the present specification will be treated as if explicitly described in the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view illustrating a conventional organic light emitting display device;

FIG. 2 is a cross-sectional view illustrating an organic light emitting display device according to one or more embodiments of the present disclosure;

FIG. 3 is a bottom view illustrating a state in which a contact is connected to an edge or peripheral portion of a first electrode in the organic light emitting display device according to FIG. 2; and

FIGS. 4 to 12 are cross-sectional views illustrating a method of manufacturing an organic light emitting display device according to one or more embodiments of the present disclosure.

### DETAILED DESCRIPTION OF THE INVENTION

Hereinafter, embodiments of the present disclosure will be described in detail with reference to accompanying drawings. Various changes to the following embodiments are possible, and the scope of the present disclosure is not limited to the following embodiments. The patent right of the present disclosure should be defined by the scope and spirit of the present disclosure as recited in the accompanying claims. In addition, embodiments of the present disclosure are intended to fully describe the present disclosure to a person having ordinary knowledge in the art to which the present disclosure pertains.

As used in this specification, a singular form may, unless definitely indicating a particular case in terms of the context, include a plural form. Also, the expressions “comprise” and/or “comprising” in this specification do not define or limit the mentioned shapes, numbers, steps, operations, members, elements, and/or groups thereof, nor do these expressions exclude the presence or addition of one or more other different shapes, numbers, steps, operations, members, elements, and/or groups thereof, or anything else in addition thereto.

Hereinafter, when it is described that a component (or a layer) is “on” another component (or another layer), it should be understood that the component may be directly on the other component, or one or more intervening components (or layers) may also be present. In contrast, when it is described that a component is directly on to another component, it should be understood that there is (are) no intervening component(s) present. In addition, the terms indicating positions, such as “on”, “upper”, “lower”, “above”, “below”, “on a first side of”, and “on opposite sides of” are intended to mean a relative position of the components.

The terms “first”, “second”, etc. may be used to describe various items, such as various elements, regions and/or parts, but the items are not limited by the terms, and it is noted that a second element is not a first element.

In addition, described hereinbelow is an organic light emitting display device using an organic light emitting diode on silicon (OLEDoS), which is a result of forming an organic light emitting diode on a silicon wafer using a semiconductor process, but it is noted that the scope of the present disclosure is not limited thereto.

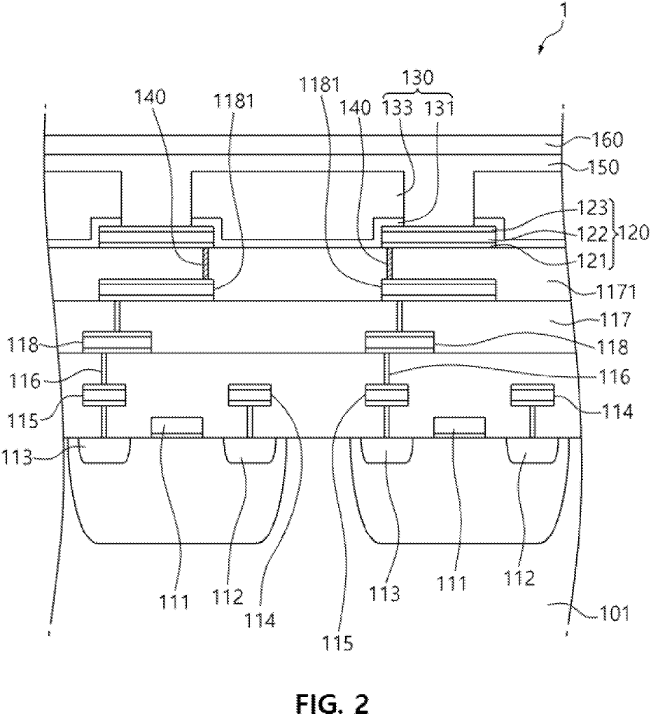

FIG. 2 is a cross-sectional view illustrating an organic light emitting display device according to one or more embodiments of the present disclosure.

Hereinafter, an organic light emitting display device 1 according to one or more embodiments of the present disclosure will be described with reference to the accompanying drawings.

Referring to FIG. 2, the present disclosure relates to an organic light emitting display device 1. More particularly, the present disclosure relates to the organic light emitting display device 1 having a fence structure between a pixel region and that covers edge or peripheral portions of adjacent first electrodes that include an anode, the organic light emitting display device 1 increasing isolation characteristics and preventing crosstalk between adjacent pixel regions, and the organic light emitting display device 1 preventing a defect that may occur in subsequent processing (e.g., following formation of a reflective electrode).

First, the organic light emitting display device 1 according to one or more embodiments of the present disclosure includes a substrate 101, such as a silicon wafer, for example. Such a substrate 101 may include a gate line, a data line, and a transistor. The gate line is connected to a gate driver and receives a gate signal, and the data line is connected to a data driver and receives a data voltage.

A gate electrode 111 is on the substrate 101, and a source 113 and a drain 112 may be on or in the substrate 101. In addition, a source electrode 115 electrically connected to the source 113 and a drain electrode 114 electrically connected to the drain 112 may be on or over the substrate 101. The source electrode 115 and the drain electrode 114 are respectively electrically connected to the source 113 and the drain 112 through separate contacts 116.

In addition, an insulation film 117 is on or over the substrate 101, and the insulation film 117 may comprise a silicon nitride film, a silicon oxide film (e.g., doped or undoped silicon dioxide), or multiple films thereof. The insulation film 117 electrically insulates the drain electrode 114, the source electrode 115, and the gate electrode 111.

Metal wirings 118 may be in the insulation film 117 and electrically connected to the gate electrode 111, the drain electrode 114 and/or the source electrode 115 through the contact 116 that extends in the vertical direction as shown in FIG. 2. In addition, each of the metal wirings 118 and the contacts 116 may be electrically insulated by the insulation film 117 and/or the underlying pre-metal dielectric layer (not numbered). Preferably, additional layers of alternating metal wirings 118 and insulation films 117 are present (but are not shown in FIG. 2) to form a multilayer wiring structure.

A first electrode 120 may be on the insulation film 117. The first electrode may be electrically connected to an upper metal wiring 1181 through an upper contact 140. The upper metal wiring 1181 may be an uppermost metallization layer in the OLED device or display, except for the first electrode 120. In addition, the first electrode 120 may comprise, in succession, a buffer electrode 121, a reflective electrode 122, and an anode 123. In addition, each first electrode 120 may be spaced apart from each other such that one first electrode 120 is in each pixel region.

The buffer electrode 121 may be on the insulation film 117 and below the reflective electrode 122, and may comprise titanium nitride (TiN) or a multilayered structure of titanium nitride (TiN) and titanium (Ti), but is not an essential component of the present disclosure. In addition, the reflective electrode 122 may comprise silver (Ag) having a high reflectivity for light in a red and a green wavelength range and/or aluminum (Al) having a high reflectivity for light in a blue wavelength range, but is not specifically limited thereto. More particularly, each reflective electrode 122 in a red pixel region and a green pixel region comprises silver (Ag), and each reflective electrode 122 in a blue pixel region comprises aluminum (Al).

The anode 123 is on the reflective electrode 122 and covers the reflective electrode 122. The anode 123 may comprise a transparent conductive film (ITO) capable of transmitting light.

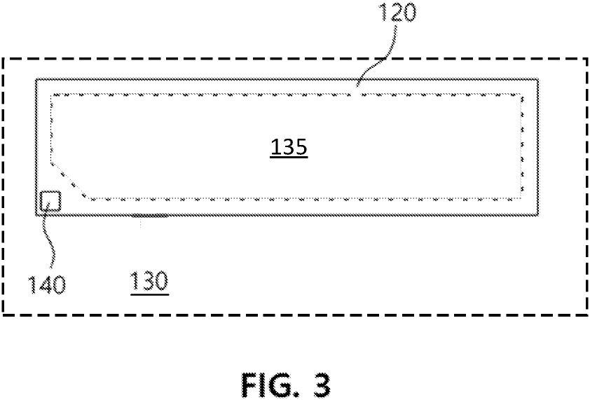

A fence structure 130 may be between first electrodes 120 in adjacent pixel regions. The fence structure 130 may be on or over the insulation film 117 or an upper insulation film 1171 at a border between the adjacent pixel regions, and the fence structure 130 covers a side surface or sidewall of each first electrode 120 and an edge or peripheral portion of the uppermost surface of each first electrode 120. For example, the fence structure 130 may have a polygonal frame shape and/or a plane shape corresponding to a frame comprising quadrangular openings therein, such that the fence structure 130 covers the sidewalls and edge or peripheral portions of the uppermost surface of the first electrodes 120 (see FIG. 3).

As such, since the fence structure 130 is between adjacent pixel regions, crosstalk between the pixel regions may be maximally prevented. In addition, when sidewalls of the reflective electrode 122 are exposed after the first electrode 120 is formed, during subsequent processing such as ashing, thermal treatment, and so on, defects on or at the surface of the reflective electrode 122 may occur due to corrosion or precipitation. As a result, the fence structure 130 advantageously prevents such defects. Therefore, the reflectivity of the reflective electrode 122 is maintained, and leakage between the adjacent pixel regions is also prevented. The fence structure 130 may be higher than the first electrodes 120 (e.g., from the uppermost surface of the upper insulation film 1171), and the fence structure 130 may have a suitable width.

In addition, the fence structure 130 may include a lower film 131 and an upper film 133.

The lower film 131 is on or over the insulation film 117 (or the upper insulation film 1171) between the adjacent pixel regions and on the side surfaces and the edges or peripheral portions of the uppermost surface of each first electrode 120. For example, the lower film 131 may serve as an etch stop film and may comprise a silicon nitride film. More specifically, the lower film 131 may function as an etch stop film when etching the upper film 133.

The upper film 133 comprises an insulation film on the lower film 131, and may comprise a silicon dioxide film formed from tetraethyl orthosilicate (TEOS) as an example, but is not specifically limited thereto. The upper surface of each first electrode 120 except for the edge or peripheral portion is not covered by the lower film 131 and the upper film 133, so that the first electrode 120 can performing a light-reflecting function. That is, the upper film 133 may also have openings with a polygonal shape exposing the uppermost surface of each first electrode 120. In addition, preferably, the upper film 133 has a width greater than that of the first electrode 120.

FIG. 3 is a bottom view illustrating the upper contact 140 connected to the edge or peripheral portion of the first electrode 120 in the organic light emitting display device according to FIG. 2.

Referring to FIGS. 2 and 3, as described above, each of the first electrodes 120 may be electrically connected to the corresponding upper metal wiring 1181 through the upper contact 140. The upper contact 140 is connected to a lowermost surface of each first electrode 120, and vertically overlaps the fence structure 130 on or over a peripheral portion of each first electrode 120. That is, the upper contact 140 is electrically connected to the first electrode 120 at an edge or peripheral location outside the region of the first electrode 120 exposed by the opening 135 in the fence structure 130. The edge or peripheral portion of the first electrode 120 covered by the fence structure 130 may not reflect much, if any, light to the overlying organic light-emitting diode layer 150. Accordingly, as compared an otherwise identical device in which the upper contact 140 is in the center of the first electrode 120, the reflective electrode 122 of the present disclosure is prevented from being bent (i.e., it has a planar or relatively planar uppermost surface in contact with the organic light-emitting diode layer 150), so that the reflective electrode 122 has a relatively high reflectivity. In FIG. 3, the outer dashed line does not indicate a border of the fence structure 130; rather, it indicates the existence of the fence structure 130 outside the sidewalls of the first electrode 120. The fence structure 130 generally continues beyond the outer dashed line shown in FIG. 3.

In describing the present disclosure again with reference to FIG. 2, an organic light emitting (diode) layer 150 is on the first electrode 120, and the organic light emitting layer (diode) 150 may include a hole transporting layer (HTL), a hole injection layer (HIL), an emitting layer (EML), an electron transporting layer (ETL), an electron injection layer (EIL), and so on. When a voltage is applied to the anode 123 and a cathode 160 (described later), holes and electrons migrate to the emitting layer and result in emission of light by recombination.

The cathode 160 is on the organic light emitting (diode) layer 150 and covers the organic light emitting (diode) layer 150. The cathode 160 may be a common (or shared) layer that is common to or shared among the pixel regions, but is not limited thereto.

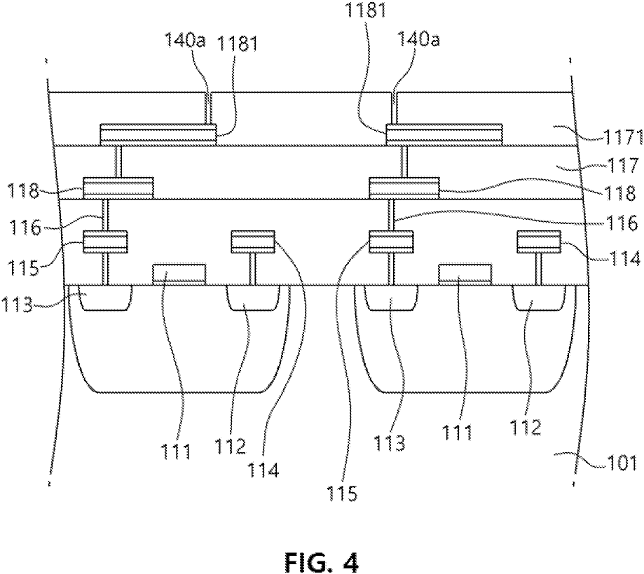

FIGS. 4 to 12 are cross-sectional views illustrating a method of manufacturing an organic light emitting display device according to one or more embodiments of the present disclosure.

Hereinafter, the present method according to one or more embodiments of the present disclosure will be described in detail with reference to the accompanying drawings. Each process may be performed in a different sequence from the described order, and it should be noted that some processes may be performed at substantially the same time. In addition, in order to clearly describe characteristics of the present disclosure, the processes for forming the first electrode 120, the fence structure 130, and the upper contact 140 will be described in detail.

First, referring to FIG. 4, the upper contact 140 is formed in the upper insulation film 1171 that covers the upper metal wiring 1181. In describing the forming process of the upper contact 140 in detail, firstly, a contact hole 140a exposing the upper metal wiring 1181 is formed in the upper insulation film 1171 by conventional photolithographic patterning (e.g., using a photoresist) and etching.

Referring to FIG. 4, for example, after a photoresist pattern (not illustrated) having an opening therein corresponding to the contact hole 140a is formed on the upper surface of the insulation film 1171, the contact hole 140a may be formed by etching the exposed upper insulation film 1171. The contact hole 140a is formed where the first electrode 120 and the upper metal wiring 1181 are connected. Eventually, the fence structure 130 overlaps the contact hole 140a in the vertical direction, after forming the first electrode 120 during subsequent processing. That is, the first electrode 120 is subsequently formed on or over the contact 140 (see FIGS. 2-3). Then, after the photoresist pattern is removed, the contact hole 140a is cleaned.

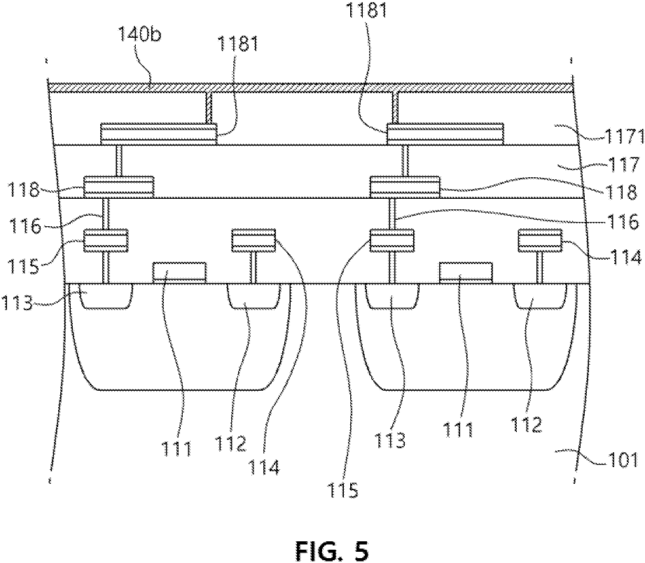

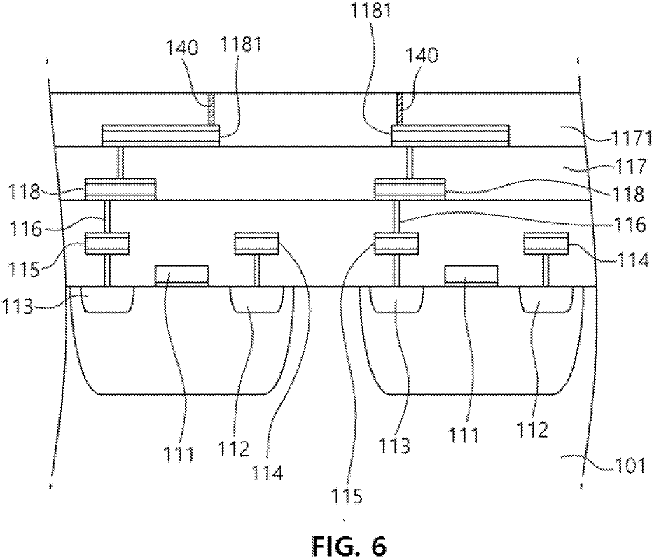

Then, referring to FIG. 5, the contact hole 140a is filled by depositing a metal layer 140b on the upper insulation film 1171 and in the contact hole 140a. For example, the metal layer 140b may comprise tungsten, but the range of the present disclosure is not limited thereto, and the metal layer 140b may more generally comprise a conductive material (e.g., Ti, TiN, Al, a combination thereof, etc.). Then, referring to FIG. 6, the metal layer 140b on the upper insulation film 1171 is removed by chemical mechanical polishing (CMP).

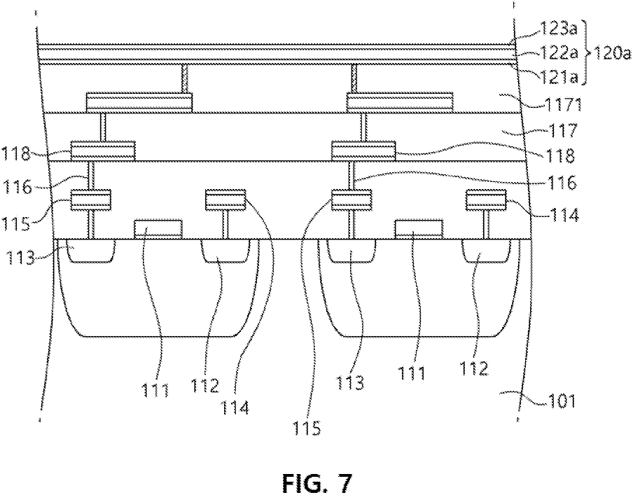

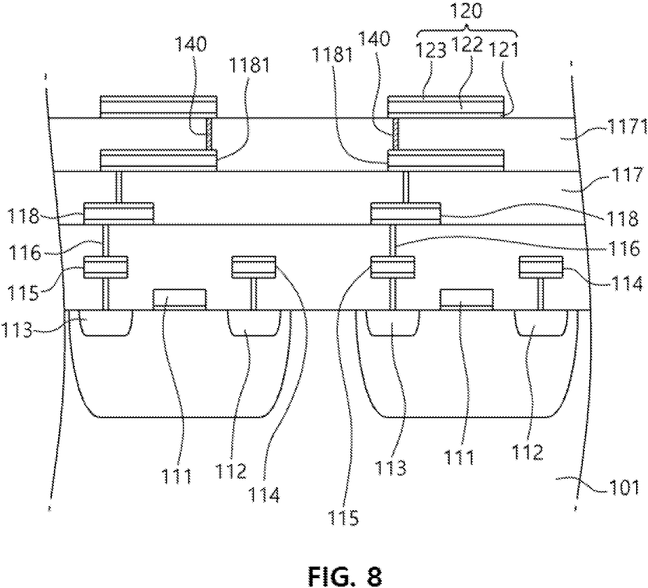

Then, the first electrode 120 is formed. The first electrode 120 may be formed by sequentially blanket-depositing the buffer electrode 121, the reflective electrode 122, and the anode 123 on the upper insulation film 1171, then patterning and etching the metal film 120a between the adjacent pixel regions. The process of forming the first electrode 120 will be described in detail. Referring to FIG. 7, after a lower metal layer 121a, a middle metal layer 122a, and an upper metal layer 123a are sequentially formed on the upper insulation film 1171, a photoresist pattern (not shown) is formed on the upper metal layer 123a. The photoresist pattern may have openings between adjacent pixel regions. Then, referring to FIG. 8, the first electrode 120 is formed by etching the metal layers 121a, 122a, and 123a exposed by the openings in the photoresist pattern.

The lower metal layer 121a may comprise titanium nitride (TiN) or a multilayered structure of titanium nitride (TiN) and titanium (Ti), the middle metal layer 122a may comprise silver (Ag) and/or aluminum (Al), and the upper metal layer may comprise a transparent conductive film such as indium tin oxide (ITO), but are not limited thereto. Then, the photoresist pattern is removed and the resulting structure is cleaned.

After the first electrodes 120 are formed, the fence structure 130 is formed on and between the first electrodes 120. As described above, the fence structure 130 may be formed on the upper insulation film 1171 between the adjacent pixel regions, and the fence structure 130 covers the side surfaces of each first electrode 120 and the upper surface of each first electrode 120 at an edge or peripheral portion thereof.

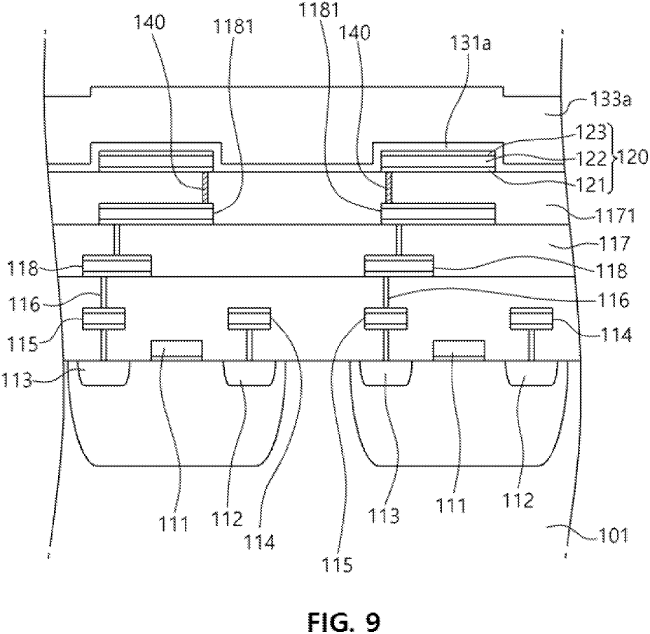

The process of forming the fence structure 130 will be described. Referring to FIG. 9, firstly, a first insulation film 131a and a second insulation film 133a are sequentially blanket-deposited on the first electrodes 120 and the upper insulation film 1171. The first insulation film 131a may comprise a silicon nitride film, and the second insulation film 133a may comprise a silicon dioxide (e.g., TEOS) film.

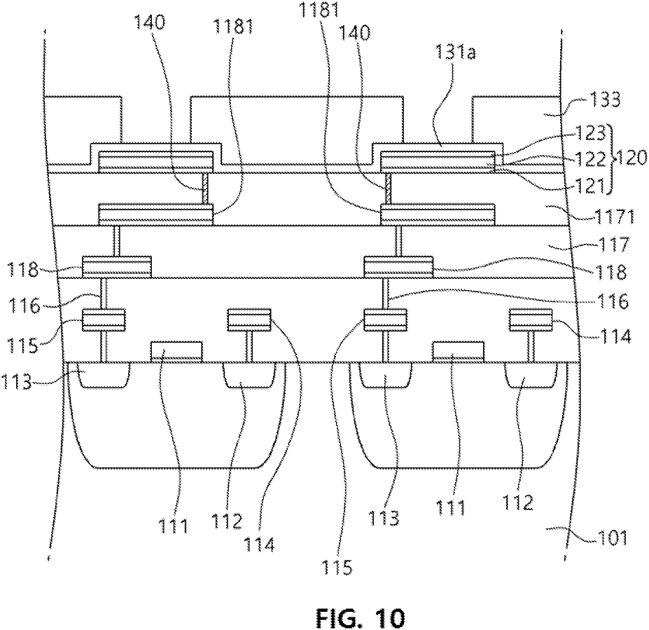

Then, referring to FIG. 10, by etching the second insulation film 133a and then etching the first insulation film 131a, the lower film 131 and the upper film 133 are formed. In detail, a photoresist pattern (not illustrated) is formed on the second insulation film 133a exposing portions of the second insulation film 133a over the first electrode 120, other than the edge or peripheral portions of the first electrode 120. After that, the exposed areas of the second insulation film 133a are etched through the openings. Accordingly, the upper film 133 is formed. When the second insulation film 133a is etched, the first insulation film 131a may serve or function as an etch stop. The photoresist pattern may then be removed, and the resulting structure may be cleaned.

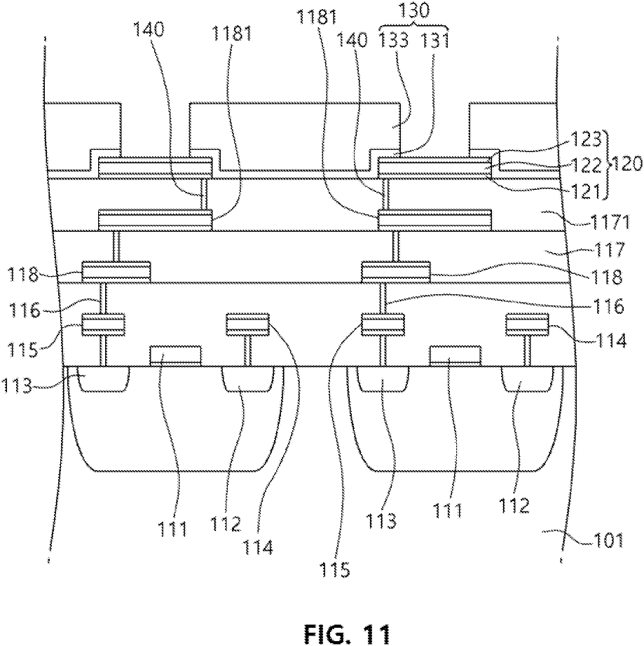

Then, referring to FIG. 11, the method may further comprise etching the first insulation film 131a over the first electrode 120 other than the edge or peripheral portions of the first electrode 120, to enable perform the first electrode 120 to reflect light.

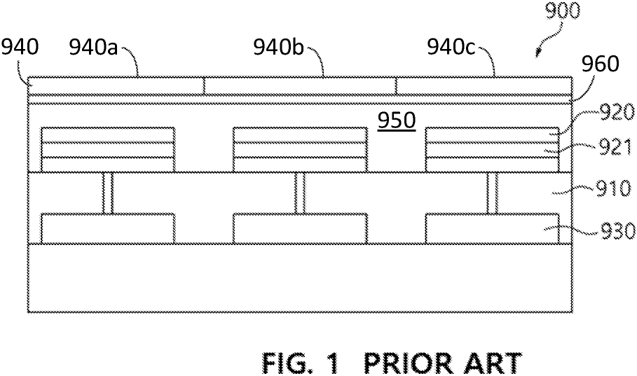

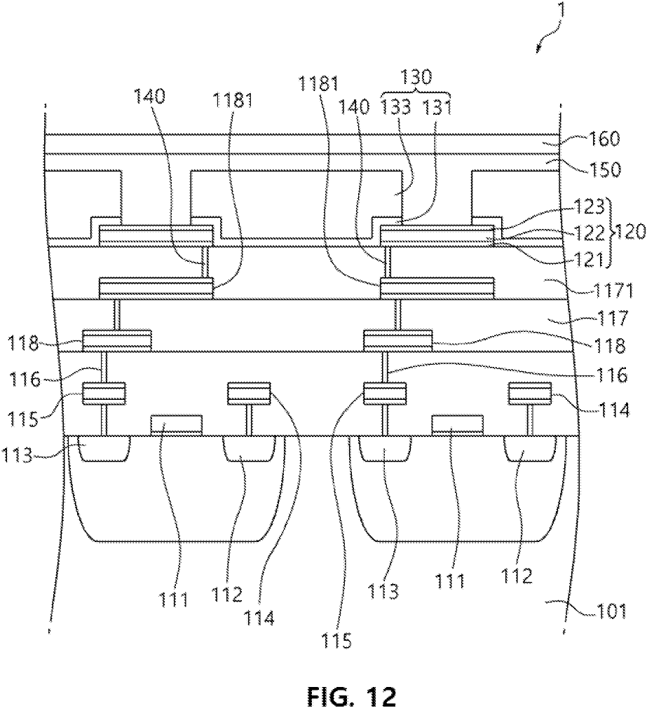

Then, referring to FIG. 12, the organic light emitting layer 150 is formed on the first electrode 120 (e.g., by blanket deposition of the functional layers therein), and the second electrode 160 is formed (e.g., by blanket deposition) on the organic light emitting layer 150. The method may further comprise forming an uppermost insulation or passivation layer on or over the second electrode 160, forming a planarization layer on or over the uppermost insulation or passivation layer, and/or forming a color filter layer on or over the planarization layer. Thus, the present OLED device or display may further comprise an uppermost insulation or passivation layer (similar to the insulation or passivation layer 950 in FIG. 1) on or over the second electrode 160, a planarization layer (similar to the planarization layer 960 in FIG. 1) on or over the uppermost insulation or passivation layer, and/or a color filter layer (similar to the color filter layer 940 in FIG. 1) on or over the planarization layer. A single insulation or passivation layer may also function as a planarization layer in the present disclosure.

The foregoing detailed description is for illustrative purpose only. Further, the description provides one or more embodiments of the present disclosure and the present disclosure may be used in other various combination, changes, and environments. That is, the present disclosure may be changed or modified within the scope of the present disclosure described herein, a range equivalent to the description, and/or within the knowledge or technology in the related art. The embodiments may show or describe an optimum state for achieving the spirit of the present disclosure and may be changed in various ways for certain applications and/or fields and use. Therefore, the detailed description of the present disclosure is not intended to limit the present disclosure in the embodiments.

What is claimed is:

1. An organic light emitting display device comprising:
metal wirings;
an insulation film covering the metal wirings;
first electrodes on the insulation film;
contacts electrically connecting each of the first electrodes to a corresponding one of the metal wirings; and
a fence structure on the insulation film between adjacent pixel regions and configured to cover only a part of adjacent ones of the first electrodes.

2. The organic light emitting display device of claim 1, wherein the fence structure covers a sidewall of each of the first electrodes.

3. The organic light emitting display device of claim 1, wherein the fence structure comprises:
a lower film on a sidewall and an edge or peripheral portion of an uppermost surface of each of the first electrodes and on the insulation film between the adjacent pixel regions; and
an upper film on the lower film.

4. The organic light emitting display device of claim 3, wherein the fence structure has a polygonal frame shape.

5. The organic light emitting display device of claim 1, wherein each of the contacts is connected to a corresponding one of the first electrodes at an edge or side of the corresponding first electrode, and each of the contacts overlaps the fence structure in a vertical direction.

6. The organic light emitting display device of claim 1, further comprising an organic light emitting diode layer on the first electrode, and a second electrode on the organic light emitting diode layer.

7. The organic light emitting display device of claim 6, further comprising an uppermost insulation, passivation and/or planarization layer on or over the second electrode, and a color filter layer on or over the uppermost insulation, passivation and/or planarization layer.

8. An organic light emitting display device comprising:
a substrate;
a gate electrode on the substrate;
a source and a drain on or in the substrate;
metal wirings on the substrate;
an insulation film covering the metal wirings;
a first electrode in each pixel region, the first electrode being on the insulation film;
a contact electrically connecting each first electrode to a corresponding one of the metal wirings; and
a fence structure on the insulation film between adjacent pixel regions and having a height greater than each first electrode.

9. The organic light emitting display device of claim 8, wherein the contact is connected to an edge or peripheral portion of the first electrode.

10. The organic light emitting display device of claim 8, wherein each first electrode comprises:
a buffer electrode on the insulation film;
a reflective electrode on the buffer electrode; and
an anode on the reflective electrode.

11. The organic light emitting display device of claim 8, wherein the fence structure covers all sidewalls of the reflective electrode.

12. The organic light emitting display device of claim 11, wherein the fence structure is between the adjacent pixel regions and covers sidewalls and edge or peripheral portions of an upper surface of adjacent first electrodes.

13. A method of manufacturing an organic light emitting display device, the method comprising:
forming a contact in an insulation film;
forming a first electrode on the insulation film in each pixel region; and
forming a fence structure between adjacent first electrodes to cover only sidewalls and edge or peripheral portions of an uppermost surface of adjacent first electrodes.

14. The method of claim 13, wherein forming the fence structure comprises:
depositing a first insulation film on the insulation film between adjacent pixel regions and on the sidewalls and the adjacent first electrodes; and
depositing a second insulation film on the first insulation film.

15. The method of claim 14, wherein forming the fence structure further comprises:
etching the second insulation film; and
opening center portions of the adjacent first electrodes by etching the first insulation film.

16. The method of claim 13, wherein forming the contact comprises:
forming a contact hole by etching the insulation film to expose a metal wiring;
filling the contact hole with a conductive material; and
removing any conductive material on an uppermost surface of the insulation film,
wherein the contact is connected to the edge or peripheral portion of each first electrode.

17. The method of claim 14, wherein the first insulation film is an etch stop for the second insulation film.

18. A method of manufacturing an organic light emitting display device, the method comprising:
stacking a metal wiring and an insulation film repeatedly on a substrate including a source and a drain such that the metal wiring forms a multilayered wiring structure;
forming a contact in the insulation film;
forming a first electrode on the insulation film in each pixel region, the first electrode comprising a reflective electrode; and
forming a fence structure on the insulation film between adjacent pixel regions.

19. The method of claim 18, wherein the first electrode comprises:
a buffer electrode on the insulation film;
the reflective electrode on the buffer electrode; and
an anode on the reflective electrode,
wherein the fence structure covers a sidewall of the reflective electrode.

20. The method of claim 19, further comprising:
forming an organic light emitting layer on the anode; and
forming a common electrode on the organic light emitting layer.
